(19) United States
(12) Patent Application Publication
(10) Pub. No.: US 2004/0046241 A1
(43) Pub. Date: Mar. 11, 2004

(54) Method of manufacturing enhanced thermal dissipation integrated circuit package

(76) Inventors: Edward G. Combs, Foster, CA (US); Neil Robert McLellan, Hong Kong (HK); Chun H. Fan, Hong Kong (HK)

Correspondence Address: Milbank, Tweed, Hadley & McCloy, LLP, One Chase Manhattan Plaza, New York, NY, 10005, US

(21) Appl. No.: 10/638,606

(22) Filed: Aug. 11, 2003

Related U.S. Application Data
(62) Division of application No. 10/104,263, filed on Mar. 22, 2002.

(51) Int. Cl. H01L 23/02; H01L 23/10; H01L 23/34; H01L 23/28

(52) U.S. Cl. 257/678; 257/706; 257/707; 257/796

(57) ABSTRACT

The present invention relates to an integrated circuit packages having a thermally conductive element thermally coupled to a heat sink and semiconductor die, and a method of manufacturing said integrated circuit package.

### FIELD OF THE INVENTION

The present invention relates to integrated circuit packaging and manufacturing thereof, and more particularly, to integrated circuit packaging for enhanced dissipation of thermal energy.

### BACKGROUND OF THE INVENTION

A semiconductor device generates a great deal of heat during normal operation. As the speed of semiconductors has increased, so too has the amount of heat generated by them. It maybe desirable to dissipate this heat from an integrated circuit package in an efficient manner.

A heat sink is one type of device used to help dissipate heat from some integrated circuit packages. Various shapes and sizes of heat sink devices have been incorporated onto, into or around integrated circuit packages for improving heat dissipation from the particular integrated circuit package. For example, U.S. Pat. No. 5,596,231 to Combs, entitled “High Power Dissipation Plastic Encapsulated Package For Integrated Circuit Die,” discloses a selectively coated heat sink attached directly on to an integrated circuit die and to a lead frame for external electrical connections.

### SUMMARY OF THE INVENTION

In one aspect, the invention features an integrated circuit package including a semiconductor die electrically connected to a substrate, a heat sink having a top portion and a plurality of side portions forming a substantially dome-like shape, wherein at least one of the side portions of the heat sink is attached to the substrate, a thermally conductive element thermally coupled with and interposed between at least a portion of the semiconductor die and at least a portion of the heat sink, and an encapsulant material encapsulating the heat sink such that a portion of the heat sink is exposed to surroundings of the package.

In another aspect, the invention features an integrated circuit package including a semiconductor die electrically connected to a substrate, a heat sink having a top portion and a plurality of side portions forming a substantially dome-like shape, means for thermally coupling the semiconductor die with the heat sink to dissipate heat from the semiconductor die to surroundings of the package, and means for encapsulating the heat sink such that a portion of the heat sink is exposed to surroundings of the package.

In another aspect, the invention features an integrated circuit package including a substrate having a first substrate surface with an electrically conductive trace formed thereon and a second substrate surface with a plurality of solder balls electrically connected thereto, wherein the trace and at least one of the plurality of solder balls are electrically connected, and a semiconductor die mounted on the first substrate surface, wherein the semiconductor is electrically connected to the trace. In accordance with this aspect of the invention, the integrated circuit package further includes a heat sink having a top portion and a plurality of side portions, wherein a thermally conductive adhesive attaches the side portions to the substrate, a thermally conductive element thermally coupled with and interposed between at least a portion of the semiconductor die and at least a portion of the heat sink, wherein the thermally conductive element is not in direct contact with the semiconductor die, a surface of the thermally conductive element aligns below a height of a plurality of bond wires, and an electrically and thermally conductive adhesive attaches the heat sink with the thermally conductive element, and an encapsulant material encapsulating at least a portion of the first substrate surface and substantially all of the heat sink except the top portion.

In yet another aspect, the invention features an integrated circuit package including a substrate having means for electrically interconnecting a semiconductor die and means for exchanging electrical signals with an outside device, the semiconductor die attached and electrically connected to the substrate by attachment means, a heat sink having a dome-like means for dissipating thermal energy to surroundings of the package, means for thermally coupling the heat sink with the semiconductor die, wherein the means for thermally coupling is interposed between at least a portion of the semiconductor die and at least a portion of the heat sink, and means for encapsulating the heat sink such that a portion of the heat sink is exposed to surroundings of the package.

In further aspect, the invention features a method of manufacturing an integrated circuit package including attaching a semiconductor die to substrate, aligning an assembly over the semiconductor die, wherein the assembly comprises a heat sink and a thermally conductive element, resting the assembly on the substrate such that the thermally conductive element does not contact the semiconductor die, and encapsulating the assembly to form a prepackage such that a portion of the heat sink is exposed to surrounding of the prepackage.

In yet another aspect, the invention features a method of manufacturing an integrated circuit package including attaching a semiconductor die to a substrate, attaching an assembly to the substrate, wherein the assembly comprises a heat sink and a thermally conductive element, and encapsulating the heat sink such that a portion of the heat sink is exposed to surroundings of the package.

### BRIEF DESCRIPTION OF THE DRAWINGS

The foregoing features and other aspects of the invention are explained in the following description taken in connection with the accompanying drawings, wherein:

FIG. 1 is a simplified cross-sectional view of an integrated circuit package 5 according to one embodiment of the present invention;

FIG. 2 is a simplified cross-sectional view of an integrated circuit package 6 according to another embodiment of the invention, which has a direct chip attachment;

FIG. 3 is a plan view of a subassembly of an integrated circuit package as shown in FIG. 1 prior to encapsulation;

FIGS. 4a and 4b illustrate major steps performed in assembly of one embodiment of an integrated circuit package 5 as shown in FIG. 1; and

FIGS. 5a and 5b illustrate major steps performed in assembly of another embodiment of an integrated circuit package 6 as shown in FIG. 2; and

It is to be understood that the drawings are exemplary, and are not deemed limiting to the full scope of the appended claims.

### DETAILED DESCRIPTION OF PREFERRED EMBODIMENTS

Various embodiments of the integrated circuit package of the present invention will now be described with reference to the drawings.

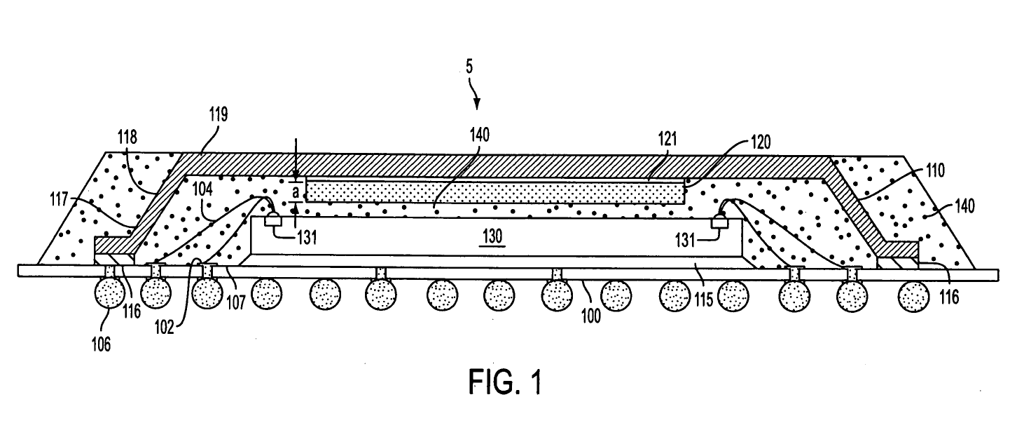

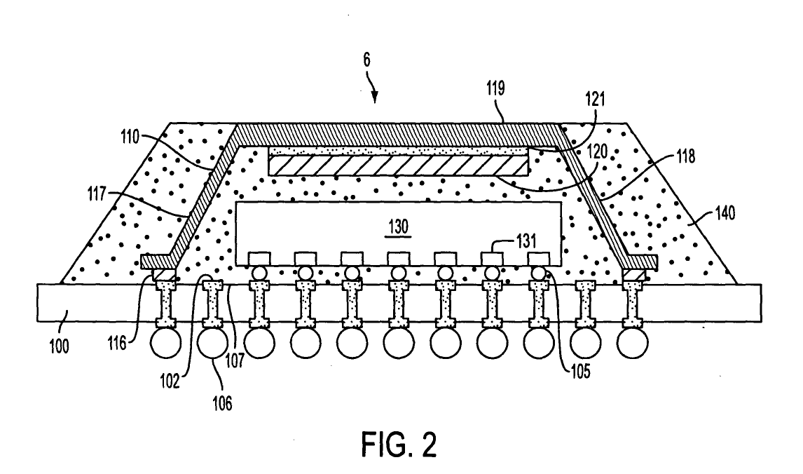

FIGS. 1 and 2 show certain components of an integrated circuit package 5, 6 according to embodiments of the present invention displayed in their respective positions relative to one another. The integrated circuit packages 5, 6 depicted in FIGS. 1 and 2 each generally includes a substrate 100, a heat sink 110, an adapter 120, a semiconductor die 130 and an encapsulant 140. Each of the foregoing will now be described in greater detail along with manufacturing steps associated with them.

A substrate 100 of either a rigid material (e.g., BT, FR4, or ceramic) or a flexible material (e.g., polyimide) has circuit traces 102 onto which a semiconductor die 130 can be interconnected using, for example, wire bonding techniques, direct chip attachment, or tape automated bonding. FIG. 1 shows a semiconductor die 130 connected to the traces 102 of the substrate 100 via a gold thermo-sonic wire bonding technique. In such an embodiment, gold wires 104 interconnect die pads 131 of the semiconductor die 130 to the traces of the substrate 100. In another embodiment, shown in FIG. 2, the semiconductor die 130 is connected to the traces 102 via a direct chip attachment technique using solder balls 105. The substrate 100 may be produced in strip form to accommodate standard semiconductor manufacturing equipment and process flows, and may also be configured in a matrix format to accommodate high-density packaging.

In the embodiments shown in FIGS. 1 and 2, the traces 102 are embedded photolithographically into the substrate 100, and are electrically conductive to provide a circuit connection between the semiconductor die 130 and the substrate 100. Such traces 102 also provide an interconnection between input and output terminals of the semiconductor die 130 and external terminals provided on the package 5, 6. In particular, the substrate 100 of the embodiment shown in FIG. 1 has a two-layer circuit trace 102 made of copper. A multilayer substrate may also be used in accordance with an embodiment. The substrate 100 shown in FIG. 1 has several vias drilled into it to connect the top and bottom portions of each circuit trace 102. Such vias are plated with copper to electrically connect the top and bottom portions of each trace 102. The substrate 100 shown in FIGS. 1 and 2 also has a solder mask 107 on the top and bottom surfaces. Such a solder mask 107 of these embodiments electrically insulates the substrate 100 and reduces wetting (i.e., reduces wanted flow of solder into the substrate 100.)

As shown in FIGS. 1 and 2, the external terminals of the package 5, 6 of certain embodiments of the present invention include an array of solder balls 106. In such embodiments, the solder balls 106 function as leads capable of providing power, signal inputs and signal outputs to the semiconductor die 130. Those solder balls are attached to corresponding traces 102 using a reflow soldering process. The solder balls 106 can be made of a variety of materials including lead (Pb) free solder. Such a configuration may be referred to as a type of ball grid array. Absent the solder balls 106, such a configuration may be referred to as a type of land grid array.

As shown in FIG. 1, the semiconductor die 130 may be mounted or attached to the substrate 100 with an adhesive material 115, such as epoxy. As shown in FIG. 2, a solder reflow process or other suitable direct chip attachment technique may also be used as an alternative way to attach the semiconductor die 130 to the substrate 100.

In the embodiments shown in FIGS. 1 and 2, the heat sink 110 is aligned with and positioned above the top surface of the semiconductor die 130, but not in contact with any portion of the semiconductor die 130. In such embodiments, the heat sink 110 is made of a thermally conductive material such as copper, aluminum, copper alloy or aluminum alloy. The heat sink 110 of the depicted embodiments is substantially dome-shaped with four substantially straight side portions 118-1 to 118-4 and a substantially flat top portion 119. In the depicted embodiments, the side portions 118-1 to 118-4 support the top portion 119 of the heat sink 110, and are attached to the substrate 100 by a thermally conductive adhesive 116, such as an epoxy. As shown, the top portion 119 of the heat sink 110 is exposed to dissipate heat generated by the semiconductor die 130.

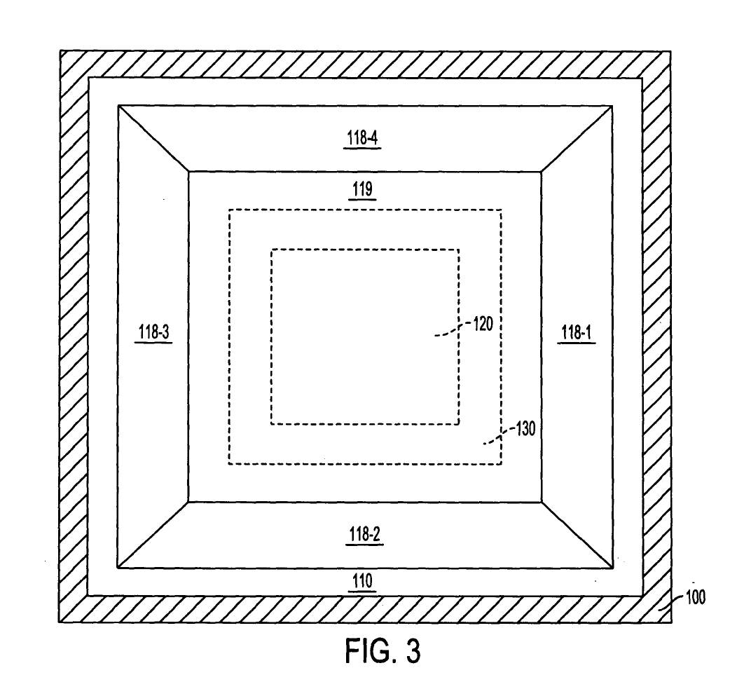

A number of configurations, shapes and sizes of heat sinks 110 may be used in accordance with embodiments of the present invention. FIG. 3 shows a plan view of one example of a geometric shape for the heat sink 110. The heat sink 110 may be sized and configured for use in a specific package arrangement. For example, the heat sink 110 may be sized such that the top portion 119 is larger than the top surface of the semiconductor die 130 (see FIG. 1).

In one embodiment, the heat sink 110 is coated with oxide 117 to enhance adhesion between the encapsulant material 140 and the heat sink 110. The oxide coating 117 may be achieved or applied by chemical reaction. In another embodiment, the heat sink may be nickel-plated. In a further embodiment, the heat sink may be anodized.

The adaptor 120 shown in FIGS. 1 and 2 helps to provide a thermal path between the semiconductor die 130 and the heat sink 110. The adaptor 120 is made of a thermally conductive material (e.g., alumina (Al₂O₃), aluminum nitride, beryllium oxide (BeO), ceramic material, copper, diamond compound, or metal) appropriate for heat transfer between the semiconductor die 130 and the heat sink 110 and, in certain embodiments, is a right rectangular solid. In one embodiment, the adaptor 120 may be shaped to compliment the dimensions and geometry of the heat sink 110 and/or the semiconductor die 130. The size of the thermally conductive element 120, particularly its thickness (shown as dimension “a” in FIG. 1), may also be selected to accommodate size variations of the semiconductor die 130 and the heat sink 110. By reducing the distance between the semiconductor die 130 and the externally exposed top portion 119 of the heat sink 110, the adaptor 120 of one embodiment may help to reduce the thermal resistance of the die-to-sink interface.

In a preferred embodiment, the distance between the upper surface of the semiconductor die 130 and the adaptor 120 is minimized to reduce the thermal resistance between the semiconductor die 130 and the heat sink 110. However, to avoid imparting stress to the semiconductor die 130, the adaptor 120 does not contact the semiconductor die 130. In one embodiment, the distance between the bottom surface of the adaptor 120 and the top surface of the semiconductor die 130 is about five (5) mils or less. As shown in FIG. 1, the adaptor 120 opposing the semiconductor die 130 is positioned such that the surface of the adaptor 120 is below the loop height of the gold wires 104 bonded to interconnect the semiconductor die 130 to the traces 102 of the substrate 100.

An adhesive layer 121, having both high thermal conductivity and deformability to minimize stress, such as an elastomer, may be used to join the adaptor 120 to the heat sink 110. In one embodiment, such an adhesive layer 119 may be electrically and thermally conductive.

As shown in FIGS. 1 and 2, portions of the heat sink 110 of these embodiments are encapsulated to form an integrated circuit package 5, 6 according to one embodiment of the present invention. The encapsulant 140 may be an epoxy-based material applied by, for example, either a liquid molding encapsulation process or a transfer molding technique.

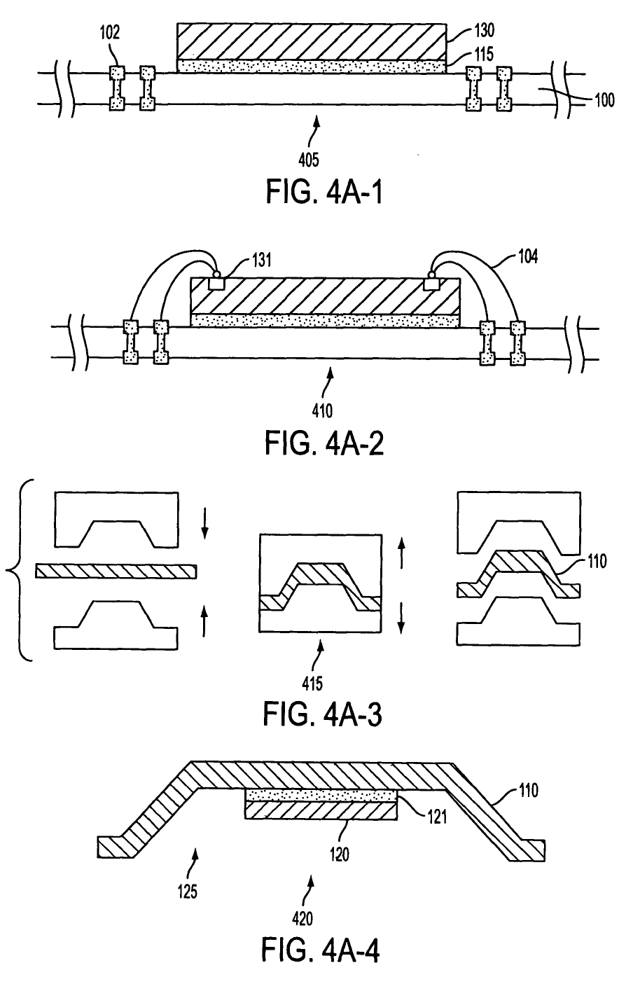

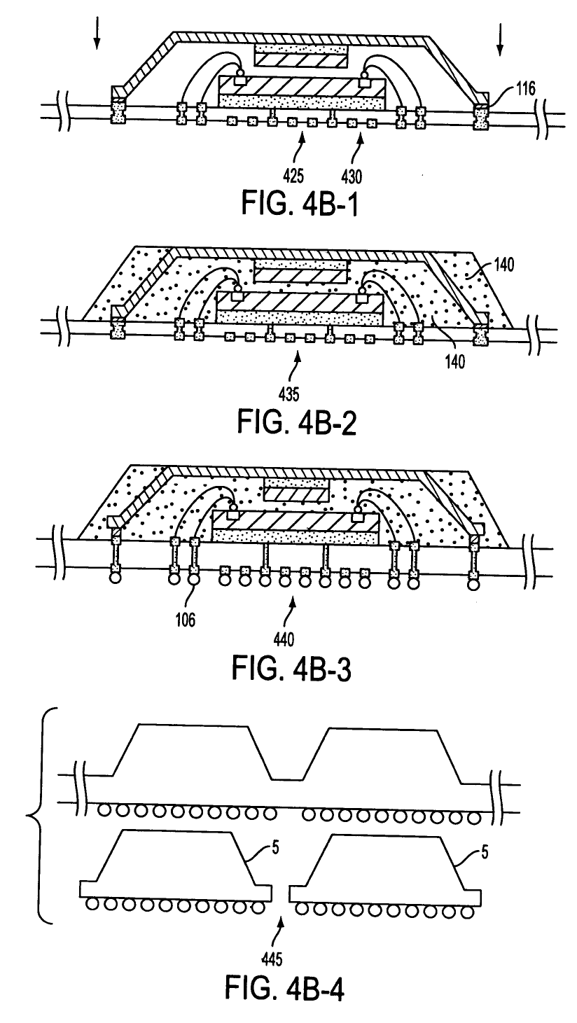

FIGS. 4a and 4b illustrate one assembly method embodiment of the invention. In this embodiment, a semiconductor die 130 is attached to a substrate 100 by an adhesive material 115 (step 405). Gold wires 104 are then connected between bond pads 131 of the semiconductor die 130 and corresponding traces 102 of the substrate 100 (step 410). A heat sink 110 is formed by stamping a flat sheet of material (e.g., copper) into a desired shape (e.g., dome with flat top and straight sides) (step 415). An adaptor 120 is then attached by an adhesive layer 121 to the heat sink 110 to form an assembly 125 (step 420). The assembly 125 is aligned with the semiconductor die 130 attached to the substrate 100 such that the adaptor 120 may be positioned in a complimentary location in relation to the semiconductor die 130 in a completed integrated circuit package (step 425). The assembly 125 is then attached to the substrate 100 by an adhesive 116 (step 430). In this embodiment, portions of the substrate 100, heat sink 110, adaptor 120, semiconductor die 130 and other components are encapsulated using, for example, a liquid molding encapsulation process or a transfer molding technique (step 435). Upon completion of the encapsulation, a top portion 112 of the heat sink 110 remains exposed to allow heat transfer and dissipation to the ambient environment of the integrated circuit package (see FIG. 1). Using a reflow soldering process, solder balls 106 are then attached to a portion of the traces 102 (step 440). After such encapsulation and ball attachment assembly steps, the substrate 100 may be singulated using a saw singulation or punching technique to form completed individual integrated circuit packages 5 (step 445).

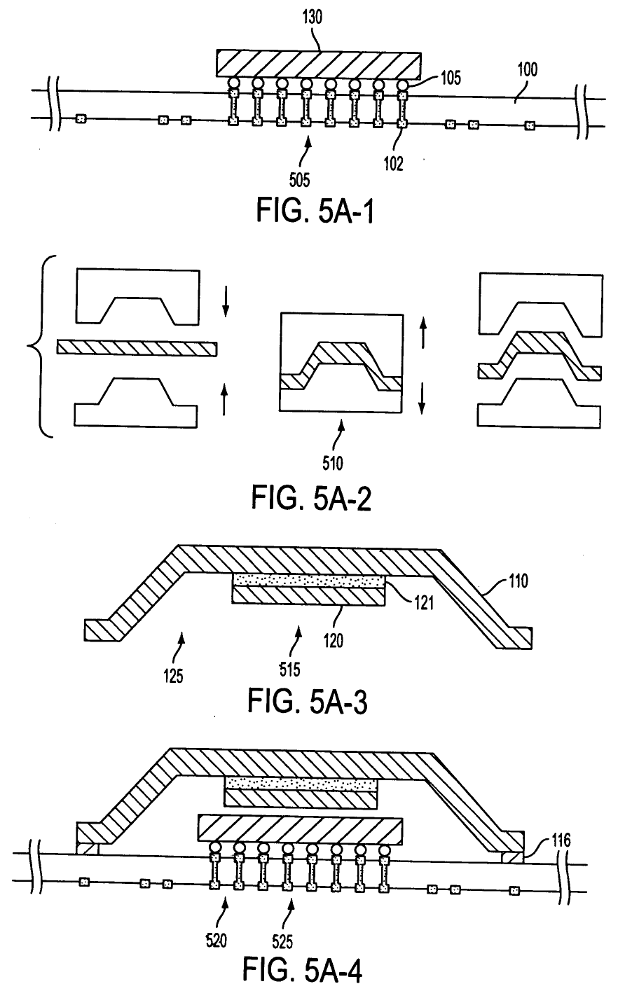

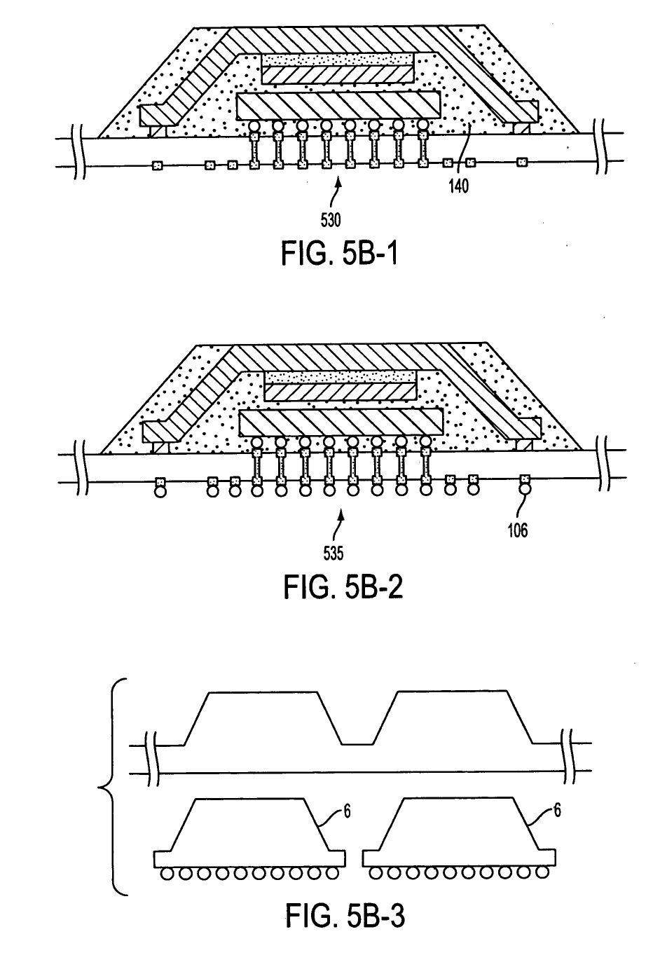

FIGS. 5a and 5b illustrate another assembly method embodiment of the invention. In this embodiment, a semiconductor die 130 is attached to a substrate 100 by a reflow soldering process such that solder balls 105 connect bond pads 131 of the semiconductor die 130 to corresponding traces 102 of the substrate 100 (step 505). A heat sink 110 is formed by stamping a flat sheet of material (e.g., copper) into a desired shape (e.g., dome with flat top and straight sides) (step 510). An adaptor 120 is then attached to the heat sink 110 by an adhesive layer 121 to form an assembly 125 (step 515). The assembly 125 is aligned with the semiconductor die 130 attached to the substrate 100 such that the adaptor 120 may be positioned in a complimentary location in relation to the semiconductor die 130 in a completed integrated circuit package (step 520). The assembly 125 is then attached to the substrate 100 by an adhesive 116 (step 525). In this embodiment, portions of the substrate 100, heat sink 110, adaptor 120, semiconductor die 130 and other components are encapsulated using, for example, a liquid molding encapsulation process or a transfer molding technique (step 530). Upon completion of the encapsulation, a top portion 112 of the heat sink 110 remains exposed to allow heat transfer and dissipation to the ambient environment of the integrated circuit package (see FIG. 2). Using a reflow soldering process, solder balls 106 are then attached to a portion of the traces 102 (step 535). After such encapsulation and ball attachment assembly steps, the substrate 100 may be singulated using a saw singulation or punching technique to form completed individual integrated circuit packages (step 540).

Although illustrative embodiments have been shown and described herein in detail, it should be noted and will be appreciated by those skilled in the art that there may be numerous variations and other embodiments which may be equivalent to those explicitly shown and described. For example, the scope of the present invention may not necessarily be limited in all cases to execution of the aforementioned steps in the order discussed. Unless otherwise specifically stated, the terms and expressions have been used herein as terms of description and not terms of limitation. Accordingly, the invention is not limited by the specific illustrated and described embodiments (or terms or expressions used to describe them) but only by the scope of the appended claims.

We claim:

1. An integrated circuit package, comprising:
a semiconductor die electrically connected to a substrate;
a heat sink having a top portion and a plurality of side portions forming a substantially dome-like shape, wherein at least one of said side portions of said heat sink is attached to said substrate;
a thermally conductive element thermally coupled with and interposed between at least a portion of said semiconductor die and at least a portion of said heat sink; and
an encapsulant material encapsulating said heat sink such that a portion of said heat sink is exposed to surroundings of said package.

2. The integrated circuit package of claim 1, wherein a distance between said thermally conductive element and said semiconductor die is five (5) mils or less.

3. The integrated circuit package of claim 1, wherein a major dimension of said thermally conductive element is smaller than a distance between two opposing rows of die pads of said semiconductor die.

4. The integrated circuit package of claim 3, wherein a surface of said thermally conductive element aligns below a height of a plurality of bond wires.

5. The integrated circuit package of claim 1, wherein said heat sink is made of a material from a group consisting of copper, aluminum, copper alloy, and aluminum alloy.

6. The integrated circuit package of claim 1, wherein said thermally conductive element is made of a material from a group consisting of alumina, aluminum nitride, beryllium oxide, ceramic material, copper, diamond compound, and metal.

7. The integrated circuit package of claim 1, wherein said heat sink comprises an oxide coating.

8. The integrated circuit package of claim 1, wherein said heat sink is mounted to said substrate by a thermally conductive adhesive.

9. The integrated circuit package of claim 1, wherein said semiconductor die is electrically connected to said substrate by a direct chip attachment.

10. An integrated circuit package, comprising:
a semiconductor die electrically connected to a substrate;
a heat sink having a top portion and a plurality of side portions forming a substantially dome-like shape;
means for thermally coupling said semiconductor die with said heat sink to dissipate heat from said semiconductor die to surroundings of said package; and
means for encapsulating said heat sink such that a portion of said heat sink is exposed to surroundings of said package.

11. An integrated circuit package, comprising:
a substrate comprising;
a first substrate surface with an electrically conductive trace formed thereon; and
a second substrate surface with a plurality of solder balls electrically connected thereto, wherein said trace and at least one of said plurality of solder balls are electrically connected;
a semiconductor die mounted on said first substrate surface, wherein said semiconductor is electrically connected to said trace;
a heat sink having a top portion and a plurality of side portions, wherein a thermally conductive adhesive attaches said side portions to said substrate;
a thermally conductive element thermally coupled with and interposed between at least a portion of said semiconductor die and at least a portion of said heat sink, wherein said thermally conductive element is not in direct contact with said semiconductor die, a surface of said thermally conductive element aligns below a height of a plurality of bond wires, and an electrically and thermally conductive adhesive attaches said heat sink with said thermally conductive element; and
an encapsulant material encapsulating at least a portion of said first substrate surface and substantially all of said heat sink except said top portion.

12. The integrated circuit package of claim 11, wherein a distance between said thermally conductive element and said semiconductor die is five (5) mils or less.

13. The integrated circuit package of claim 11, wherein a major dimension of said thermally conductive element is smaller than a distance between two opposing rows of die pads of said semiconductor.

14. The integrated circuit package of claim 13, wherein a surface of said thermally conductive element aligns below a height of a plurality of bond wires.

15. The integrated circuit package of claim 11, wherein said heat sink is made of a material from a group consisting of copper, aluminum, copper alloy, and aluminum alloy.

16. The integrated circuit package of claim 11, wherein said thermally conductive element is made of a material from a group consisting of alumina, aluminum nitride, beryllium oxide, ceramic material, copper, diamond compound, and metal.

17. The integrated circuit package of claim 11, wherein said heat sink comprises an oxide coating.

18. The integrated circuit package of claim 11, wherein said semiconductor die is electrically connected to said first substrate surface of said substrate by direct chip attachment.

19. An integrated circuit package, comprising:
a substrate comprising:
means for electrically interconnecting a semiconductor die; and
means for exchanging electrical signals with an outside device;
said semiconductor die attached and electrically connected to said substrate by attachment means;
a heat sink having a dome-like means for dissipating thermal energy to surroundings of said package;
means for thermally coupling said heat sink with said semiconductor die, wherein said means for thermally coupling is interposed between at least a portion of said semiconductor die and at least a portion of said heat sink; and
means for encapsulating said heat sink such that a portion of said heat sink is exposed to surroundings of said package.

20. A method of manufacturing an integrated circuit package, comprising
attaching a semiconductor die to a substrate;
aligning an assembly over said semiconductor die, wherein said assembly comprises a heat sink and a thermally conductive element;
resting said assembly on said substrate such that said thermally conductive element does not contact said semiconductor die, and
encapsulating said assembly to form a prepackage such that a portion of said heat sink is exposed to surrounding of said prepackage.

21. The method of claim 20, wherein said assembly is rested on said substrate such that said thermally conductive element and said semiconductor die are separated by a distance of about five (5) mils or less.

22. The method of claim 20, wherein a surface of the thermally conductive element aligns below a height of a bond wire.

23. The method of claim 20, wherein said attaching said semiconductor die to said substrate is by direct chip attachment.

24. The method of claim 20, further comprising singulating said prepackage to form said package.

25. The method of claim 20, further comprising forming a substantially dome-shaped heat sink comprising a flat top portion and a plurality of straight side portions.

26. A method of manufacturing an integrated circuit package, comprising:
attaching a semiconductor die to a substrate;
attaching an assembly to said substrate, wherein said assembly comprises a heat sink and a thermally conductive element; and
encapsulating said heat sink such that a portion of said heat sink is exposed to surroundings of said package.

27. The method of claim 26, wherein said assembly is attached to said substrate such that said thermally conductive element and semiconductor die are separated by a distance of five (5) mils or less.

28. The method of claim 26, wherein a surface of the thermally conductive element aligns below a height of a plurality of bond wires.

29. The method of claim 26, wherein said attaching said semiconductor die to said substrate is by direct chip attachment.

30. The method of claim 26, further comprising singulating said prepackage to form said package.

31. The method of claim 26, further comprising forming a substantially dome-shaped heat sink comprising a flat top portion and a plurality of straight side portions.
